(19) United States
(12) Patent Application Publication
(10) Pub. No.: US 2008/0306698 A1
(43) Pub. Date: Dec. 11, 2008

(54) Method and Device for Estimating the Current Output By an Alternator for a Motor Vehicle

(75) Inventors: Jean-Marie Pierret, Paris (FR); Raymond Rechdan, Saint Maurice (FR)

Correspondence Address: MATTHEW R. JENKINS, ESQ., 2310 FAR HILLS BUILDING, DAYTON, OH, 45419, US

(73) Assignee: VALEO EQUIPEMENTS ELECTRIQUES MOTEUR, Creteil Cedex (FR)

(21) Appl. No.: 11/912,931

(22) PCT Filed: May 16, 2006
(86) PCT No.: PCT/FR06/50444

§ 371 Date: Jun. 17, 2008

(30) Foreign Application Priority Data
May 31, 2005 (FR) 0505498
Oct. 20, 2005 (FR) 0510703
May 15, 2006 (FR) PCT/FR2006/050444

(51) Int. Cl. G01R 31/34

(52) U.S. Cl. 702/60; 322/99; 702/64

(57) ABSTRACT

A method and device for estimating the current output by an alternator for a motor vehicle provide the calculation of an output value (IALT) that represents the current output by the alternator based on a first input value (lex) that represents an excitation current of the alternator, and based on a second input value (ROT) that represents the rotational speed of the alternator.

### FIELD OF THE INVENTION

The present invention concerns a method and device for estimating the current output by an alternator (or an alternator starter) for a motor vehicle. It also concerns a unit for regulating the voltage delivered by such a machine, commonly referred to as an alternator regulator.

### BACKGROUND OF THE INVENTION

The invention applies to all types of vehicle requiring, for example, a management of the engine tick-over while taking account of the torque imposed by the alternator on the thermal engine during calls for charging (this torque depending greatly on the current delivered by the alternator), and/or a sophisticated management of the vehicle battery charging balance. The method and device make it possible in fact to supply to an engine control unit or to any other computer internal to the vehicle an estimated value of the current delivered by the alternator.

The information normally delivered by the alternator is the duty cycle ratio of the excitation signal (PWM) and/or the level of the excitation current measured for example by the battery voltage regulator (see document WO 02/071570). This information is processed by the computers in order to derive therefrom the output current and the torque of the alternator.

The duty cycle ratio of the excitation signal is however poor information for deriving therefrom the value of the current and the torque delivered by the alternator. This is because the resistance of the rotor varies greatly with temperature and the duty cycle ratio of the excitation signal supplies a poor image of the excitation current, which is then used to estimate the current and torque delivered by the alternator. This problem can be partially remedied by involving the temperature of the regulator (easier to measure than the temperature of the field winding, which is in rotation), but this compensation remains approximate since the temperature of the regulator is not directly linked to the temperature of the field winding.

The excitation current is already better information for deriving therefrom the value of the current and the torque delivered by the alternator. This is because the excitation current passes through the battery voltage regulator and can easily be measured by the latter (for example via a shunt or a current mirror). However, the computer of a vehicle using this information must have in memory the characteristics (in the form of tables of pre-recorded values) of all the alternators that may be mounted on this vehicle, which uses a large memory size in the computer and is an onerous task for the manufacturer of the vehicle.

One means for avoiding these problems would be for the alternator itself to deliver the current value that it is outputting, which can be achieved in various ways.

It is possible to use a shunt or any other sensor directly measuring the current output by the alternator. However, this would greatly complicate the mechanical architecture of the alternator through additional connections and components. In addition, the shunt would have to withstand current of around 200 amperes without excessive heating (a few watts only), which would make the measurement imprecise since it would be necessary to measure voltages of a few millivolts or around ten millivolts at the terminals of the shunt.

It would also be possible to provide for the determination of the output of the alternator from the excitation current, carried out by the battery voltage regulator. Such a determination, carried out in conformity with the aforementioned prior art, would however require a large memory size incompatible with the limited memory size of the microcontrollers incorporated in conventional voltage regulators. This determination is in fact normally carried out using a complex table. This table must store the value of the output according to the speed of rotation of the alternator, the excitation current, the temperature and the battery voltage measured by the regulator. Even by making interpolations between the values given by the table, the resources necessary are incompatible with the memory size available in the small microcontrollers incorporated in regulators.

The solution proposed here, according to embodiments of the present invention, consists of calculating the output from the measurement of the excitation current and in accordance with a simplified equivalent diagram of the alternator.

### SUMMARY OF THE INVENTION

According to a first aspect, the invention proposes in fact a method of estimating the current delivered by an alternator for a motor vehicle comprising the calculation of an output value representing the current delivered by the alternator from a first input value representing an excitation current of the alternator on the one hand, and a second input value representing the rotation speed of the alternator on the other hand, the calculation of the output value comprising the steps of:

(a) calculating a first term substantially proportional to the first input value;
(b) calculating a second term substantially inversely proportional to the second input value; and
(c) subtracting the second term from the first term in order to obtain the output value.

The introduction of corrective coefficients makes it possible to adjust the result of the calculation to the actual value of the output of a predetermined alternator.

The method can be implemented at a unit regulating the voltage delivered by the alternator (commonly referred to as a battery voltage regulator or a regulator).

For example, at step (b), the second input value can be increased by a first determined non-zero additive value. This first additive value, which may be constant, makes it possible to effect an x-axis shift on the second input value for the characteristic giving the output value as a function of the second input value. This makes it possible to take account of the threshold of the rotation speed (referred to as the initiation speed) below which an alternator does not in principle output any current, by shifting the value representing the speed of rotation of the alternator.

Likewise, at step (a), the first input value can be increased by a second non-zero additive value. This second additive value, which may be constant, makes it possible to effect a y-axis shift on the first input value for the characteristic giving the output value as a function of the first input value. This makes it possible to compensate for the remanence effect of the magnetic circuit on the excitation by shifting the value representing the excitation current.

Equally, the calculation of the output value can also comprise, after step (c), the addition of a third non-zero additive value. This third additive value, which may be constant, makes it possible to effect a y-axis shift on the output value for the characteristic giving the output value as a function of the first input value and the second input value. This makes it possible in particular to take account of the efficiency of the machine.

### BRIEF DESCRIPTION OF THE DRAWINGS

In one embodiment, the second term depends on a parameter representing the temperature of the armature windings of the alternator. In this way the variation in the output of the alternator is taken account of as a function of this temperature.

In a variant, a set of parameters is selected as a function of a parameter representing the temperature of the armature windings of the alternator. This set of parameters comprises a first multiplying coefficient involved at step (a), a second multiplying coefficient involved at step (b), the first additive value, the second additive value and/or the third additive value.

In either case, the parameter representing the temperature of the armature windings of the alternator can for example be measured at the regulator. This measurement is easier to make than a measurement at the armature windings, the temperature at the regulator being however a function of the temperature at these windings, given the proximity between the two.

In one embodiment, the first input value (representing the excitation current) is also measured at the unit regulating the voltage delivered by the alternator. It is thus possible to take advantage of the method described in the aforementioned document WO 02/071570.

A second aspect of the invention relates to a device for estimating the current delivered by an alternator for a motor vehicle comprising means of calculating an output value representing the current delivered by the alternator that are configured to calculate the said output value from a first input value representing an excitation current of the alternator on the one hand, and a second input value representing the rotation speed of the alternator on the other hand, in which the means of calculating the output value comprise:

(a) first calculation means configured to calculate a first term substantially proportional to the first input value;
(b) second calculation means configured to calculate a second term substantially inversely proportional to the second input value; and
(c) third calculation means configured to subtract the second term from the first term in order to obtain its output value.

The device can advantageously comprise means for implementing the particular embodiments of the method that were presented above.

Such a device can be produced in the form of a correctly programmed microcontroller.

A third aspect of the invention relates to a unit for regulating the voltage delivered by an alternator for a motor vehicle, comprising a device for estimating the current delivered by the alternator according to the second aspect.

In one embodiment, the regulation unit also comprises means of calculating the torque applied to the alternator shaft. This torque (or turning moment) is the mechanical torque transmitted by the alternator to the thermal engine of the motor vehicle. Its taking into account by an engine control unit (such as an injection computer, for example) makes it possible to adapt the quantity of fuel injected into the thermal engine. It is thus possible to avoid problems of unwanted adjustments to the thermal engine due to the regulation of the battery charging current.

For example, the torque applied to the alternator shaft is calculated as the sum of the useful torque, the torque related to the electrical losses, and the torque related to the mechanical losses.

The useful torque can be calculated as the ratio of the useful power to the rotation speed of the alternator, the useful power being calculated as the product of the output voltage of the alternator and the level (estimated according to the method according to the first aspect) of the current delivered by the alternator.

The torque relating to electrical losses can be calculated as the ratio of the electrical losses to the rotation speed of the alternator, the electrical losses being for example calculated by virtue of a second-order function of the estimated value (estimated according to the method according to the first aspect) of the current delivered by the alternator.

The torque relating to mechanical losses can be calculated by virtue of a second-degree function of the rotation speed of the alternator.

In yet another embodiment, the regulation unit also comprises means of calculating the efficiency of the alternator. This efficiency can for example be calculated as the ratio of the useful torque to the torque applied to the alternator shaft. Supplying the level of efficiency of the alternator may be an advantage for example for diagnosis and/or maintenance operations.

Finally, a fourth aspect of the invention relates to an alternator for a motor vehicle, comprising a unit for regulating the voltage delivered by the alternator according to the third aspect.

### DESCRIPTION OF THE PREFERRED EMBODIMENTS

Other characteristics and advantages of the invention will also emerge from a reading of the following description. The latter is purely illustrative and must be read with regard to the accompanying drawings, in which:

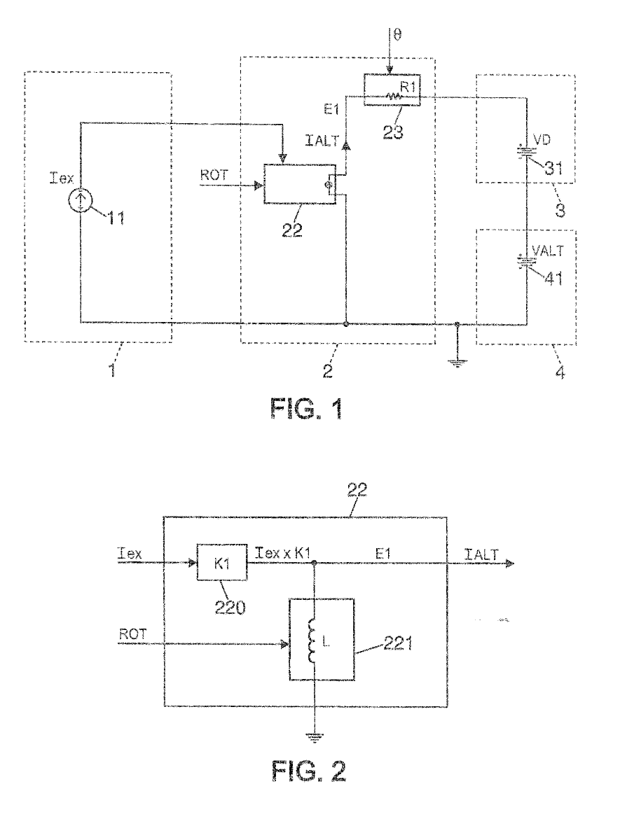

FIG. 1 is a simplified equivalent diagram of an alternator (or an alternator starter) in operation, according to an example of modelling;

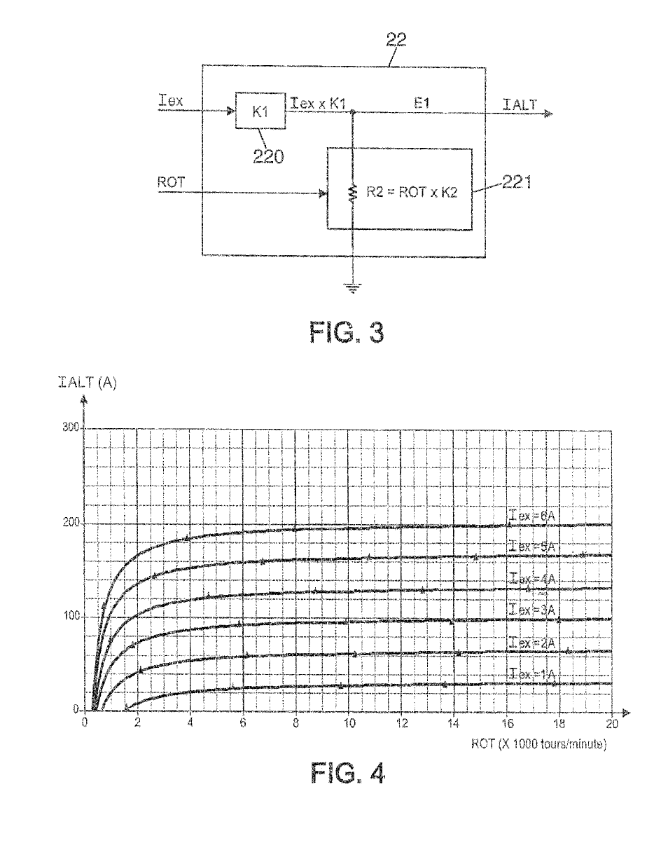

FIG. 2 and FIG. 3 are diagrams illustrating respectively a first example and a second example of modelling of the armature of an alternator;

FIG. 4 is a graph showing a grid of characteristics giving the output value (representing the output of the alternator) as a function of the second input value (representing the rotation speed of the alternator) without taking into account additive values;

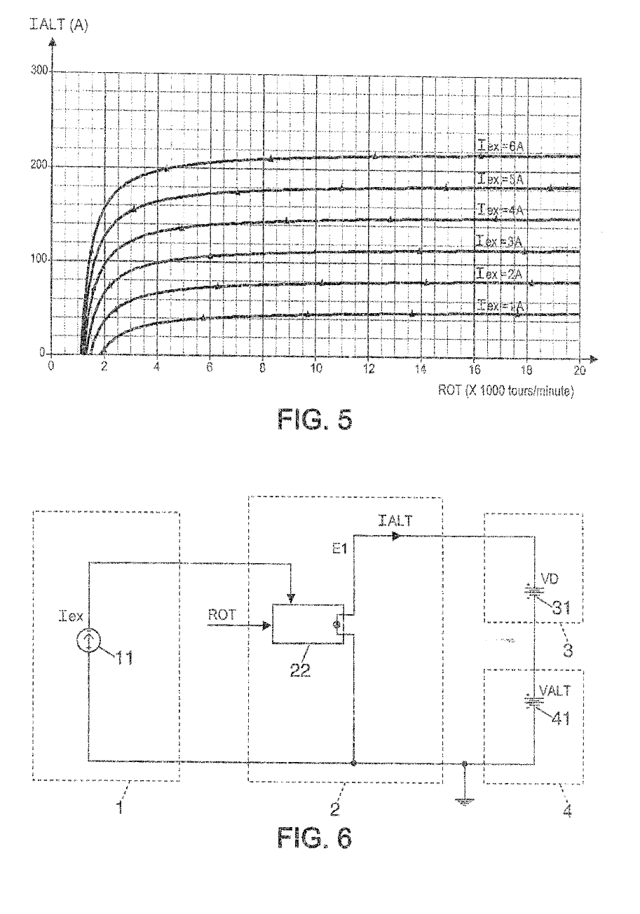

FIG. 5 is a graph showing a grid of characteristics giving the output value (representing the output of the alternator) as a function of the second input value (representing the rotation speed of the alternator), with additive values making it possible to approach the characteristics giving the current delivered by the alternator as a function of its rotation speed, recorded on a real alternator;

FIG. 6 is an equivalent diagram of an alternator in operation, according to another example of modelling enabling the calculations to be simplified;

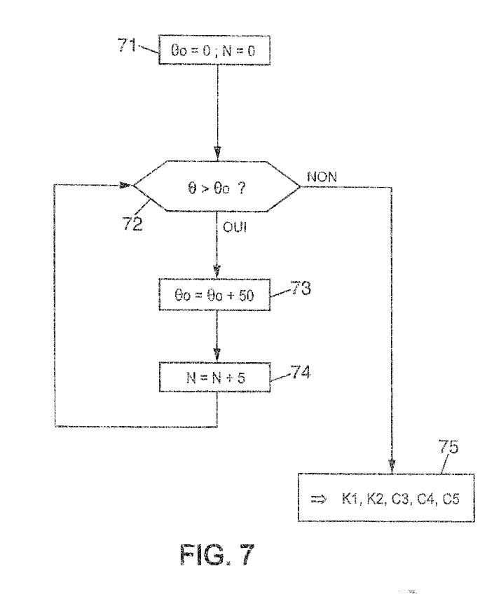

FIG. 7 is a step diagram illustrating an example of an algorithm for selecting the multiplying coefficients and the additive values, for a given temperature of the armature windings, in the context of the modelling in FIG. 6;

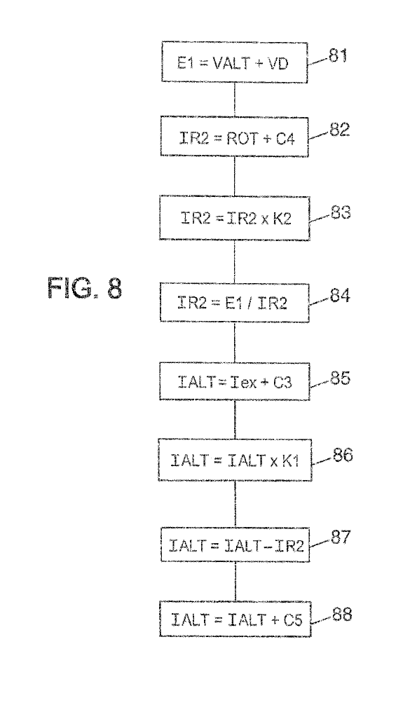

FIG. 8 is a step diagram illustrating an example of an algorithm for calculating the output of the alternator with the modelling in FIG. 6;

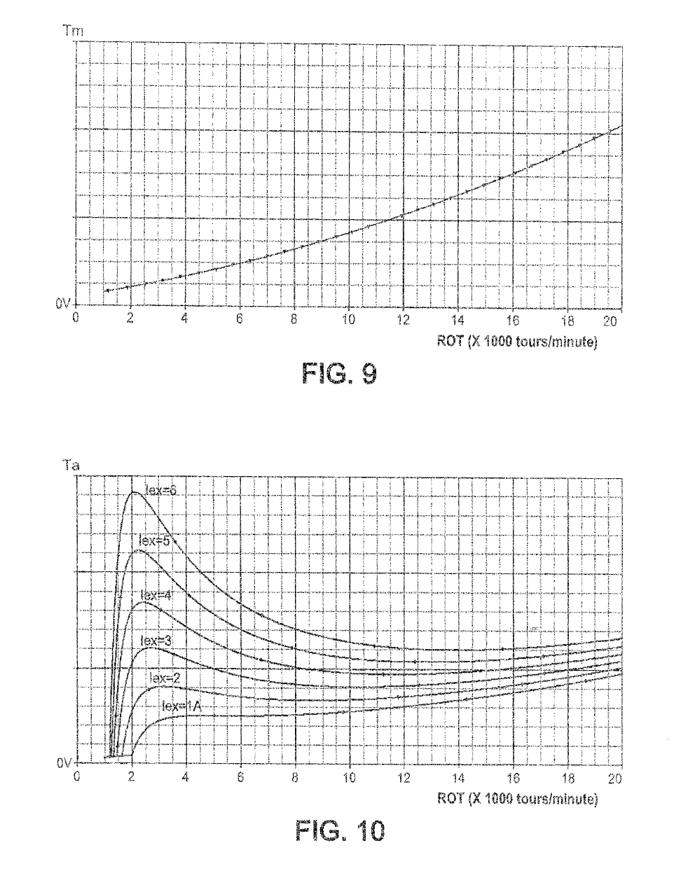

FIG. 9 is a graph giving the trend of the torque relating to mechanical losses as a function of the rotation speed, as calculated in embodiments of the present invention;

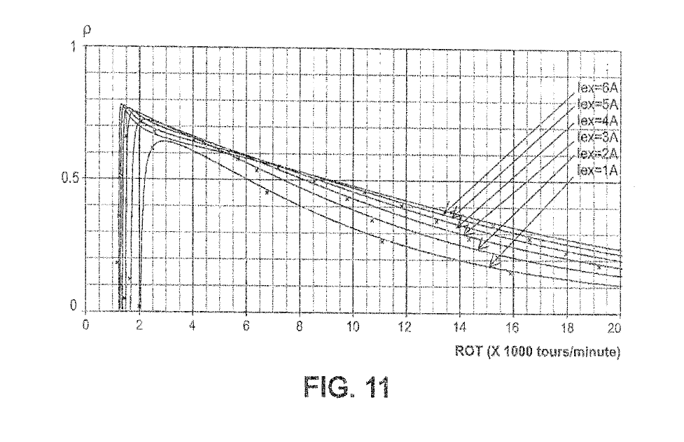

FIG. 10 is a graph giving the trend of the torque applied to the shaft of an alternator as a function of the rotation speed, as calculated in embodiments of the present invention for various values of the excitation current; and

FIG. 11 is a graph giving the trend of the efficiency of an alternator as a function of the rotation speed, as calculated in embodiments of the present invention for various values of the excitation current.

With reference to FIG. 1, a simplified equivalent diagram of an alternator will be presented, in which the various parameters are not modelled in alternating mode. This is because, in order to simplify the calculations used in the microcontroller of the alternator regulator, only equivalent continuous parameters (in currents and voltages) are considered for modelling the real alternator output. Consequently the simplified equivalent diagram does not involve any alternating current or voltage that it must be necessary to rectify. In particular, the inductors (whose impedances increase proportionally to the rotation speed) are replaced by resistors whose values also increase proportionally to the rotation speed.

The field winding 1 (for example the rotor) of the alternator is shown at the left-hand part of FIG. 1. The excitation current lex of the alternator is modelled by a DC current source 11. This current (very real) is for example measured by the regulator. In this way, the variation in resistance of the field winding as a function of temperature is taken into account in the calculations, as well as the effect of the supply voltage of the field winding.

The armature 2 (for example the stator) is shown at the middle part of FIG. 1. This armature comprises a DC current source 22 and a resistor 23 of value RI representing the actual resistance of the armature. The current source 22 delivers a DC current that corresponds to the current delivered by the alternator (induced current), as a function of the excitation current lex and the rotation speed ROT of the alternator. This current passes through the resistor 23. The rotation speed is measured in a known manner, by any appropriate sensor, for example a Hall effect sensor, or more simply from the phase voltages whose frequency is proportional to the rotation speed. In practice, the resistance R1 depends on the temperature θ of the armature windings. This temperature can be measured by an appropriate sensor, disposed at these windings. It will be seen later, however, that it is possible to do otherwise when the temperature of the windings cannot be measured easily.

The right-hand part of FIG. 1 comprises a DC voltage source 31 that models the voltage drop VD in the bridge rectifier 3 of the alternator, and a DC voltage source 41 that models the load 4 to which the output voltage VALT of the alternator is applied. The output voltage VALT of the alternator is measured by the regulator and is regulated by the latter.

With reference to FIGS. 1 and 2, the current source 22 delivers the current value IALT output by the alternator as a function of the excitation current lex, the rotation speed ROT and the value of the electromotive force E1.

This electromotive force E1 is equal to the sum of the output voltage VALT, the voltage drop in the bridge rectifier VD and the voltage drop in the resistor R1, in accordance with the following equation:

E1=VALT+VD+R1×IALT (1)

As a first approximation and at high rotation speeds (around 20000 rev/min), it can be estimated that the output of the alternator is proportional to the excitation current. There is then the following equation:

IALT=K1×lex (2)

where K1 is a given multiplying coefficient, for example a constant.

On the other hand, the alternator armature comprises a principal stator inductor 221, of value L, which diverts all or some of the current K1×lex to earth. This inductor has an impedance Lω proportional to the rotation speed ROT of the alternator. Consequently the current diverted by the inductor 221 is low at high rotation speeds and high at low rotation speeds of the alternator (around 1000 to 1200 rev/min). At very low rotation speeds (below the initiation speed, as from which the alternator commences output), all the current K1×lex is diverted by the inductor 221. The equivalent diagram then represents an alternator whose rotation speed is too low to be able to output.

With reference to FIG. 3, the equivalent diagram functioning only in continuous mode, the impedance Lω of the inductor 221 is replaced by a resistor R2 whose value is proportional to the rotation speed ROT, in accordance with the equation:

Lω=K2×ROT (3)

where K2 is a given multiplying coefficient, for example a constant.

The current I_{L} diverted by this resistor is given by:

$${I}_{L} = \frac{E 1}{( ROT \times K 2 )} \qquad ( 4 )$$

The output IALT of the alternator, which is equal to IALT=lex×K1−I_{L}, is then given by the equation:

$$IALT = lex \times K 1 - \frac{E 1}{( ROT \times K 2 )} \\ with E 1 = VALT + VD + R 1 \times IALT . \qquad ( 5 )$$

The resistance R1 depends on the temperature θ of the armature windings, in accordance with an equation of the type:

R1=Ro×(1+αθ) (6)

where θ designates the temperature of the armature winding or, failing this, the temperature at the battery voltage regulator when the temperature of the windings cannot easily be measured;

where Ro designates the resistance of the armature for a temperature of 0° C.; and

where α designates a given coefficient.

The variation in the voltage drop VD in the bridge rectifier is considered to be negligible so that VD is considered to be a constant (typically, VD is equal to approximately 2 volts). Likewise, the output voltage of the alternator VALT can be considered to be constant, because of the regulation (typically VALT is equal to approximately 14.5 volts). Equation (5) therefore gives a grid of characteristics of the output as a function of the rotation speed ROT, for various values of the excitation current lex.

As illustrated in FIG. 4, this grid of characteristics IALT=f(lex) has the trend of the grid of characteristics recorded on a real alternator.

In order to refine the modelling of the alternator, it is possible to choose constants that make it possible to make the value of IALT calculated in accordance with the model proposed to correspond exactly with the output of a real alternator. For this purpose additive values C3, C4 and C5 are introduced, which act as follows:

$$IALT = ( lex + C 3 ) \times K 1 - \frac{E 1}{( ROT + C 4 ) \times K 2} + C 5 \qquad ( 7 )$$

In summary, the value of lex is given according to the model adopted by the three equations (1), (6) and (7) given above. The meaning or role of each multiplying coefficient and each additive value (which is preferably a constant) is as follows:

K1 is the ratio between the output current IALT and the excitation current lexc of the alternator at a high rotation speed. This coefficient takes account of the ratio of the number of turns between the field winding and armature, and the loss of flux between the rotor and the stator;

K2 makes it possible to control the variation in the output current IALT as a function of the rotation speed ROT, by diverting to earth all or part of the current (lex+C3)×K1;

C3 makes it possible to take into account the effect of the remanence of the magnetic circuit on the excitation by shifting the value of the excitation current;

C4 makes it possible to effect an x-axis shift on the rotation value ROT for the characteristic IALT=f(ROT); and

C5 makes it possible to effect a y-axis shift on the value of the output IALT for the characteristic IALT=f(ROT).

The constants C3, C4 and C5 are each coded in 1 byte and act by addition. They are therefore easy to use for an 8-bit microcontroller.

The coefficient K2 acts by multiplication. Its value is imprecise and the multiplication can generally be performed easily by simple shifts of the value ROT+C4. For this purpose, K2 is chosen equal to the integer power of 2 closest to the required value. As required, if a greater precision proves necessary, it is possible to use the multiplication function generally hard-wired into 8-bit microcontrollers.

The coefficient K1 also acts by multiplication. On the other hand, it must have a precise value and it may be necessary to use the multiplication function generally hard-wired into 8-bit microcontrollers.

The choice of the value of the multiplying coefficients K1 and K2 and the constants C3, C4 and C5 is guided by the search for the correlation between the equivalent diagram of the alternator and a real alternator. It is a case of calculating or adjusting the values of the constants and coefficients so that the value IALT corresponds exactly to the output of the real alternator. It is possible to proceed according to a method by successive approximations.

At the start, it is possible to ignore the constants C3, C4 and C5 (so that C3=C4=C5=0), it is possible to ignore R1 (so that E1=VALT+VD), and K1 can be chosen so that K1=IALT/lex.

The values of the constants and coefficients are then obtained by successive approximations, noteworthy points on the curves of the characteristics IALT=f(ROT) making it possible to obtain them more easily by the use of simplified expressions.

For example, at a high rotation speed (around 20000 rev/min), the principal inductance of the armature has a very high value and the equivalent resistance R2 diverts only a negligible current. In this case, equation (7) is written:

IALT=((lex+C3)×K1)+C5 (8)

In addition, at the initiation point, IALT=0. In this case, equation (7) is written:

$$( ( lex + C 3 ) \times K 1 ) + C 5 = \frac{E 1}{( ROT + C 4 ) \times K 2} \qquad ( 9 )$$

It should be noted that, for greater precision, at least some of the parameters of the model (multiplying coefficients or additive values) can be determined dynamically, that is to say by making the alternator function. For example, it is possible to make an alternator function so that it outputs a current of given value, and to determine the additive value C1 from a measurement of the corresponding rotation speed ROT. This operation can form part of the adjustments or settings carried out at the end of the assembly line.

The grid of characteristics IALT=f(lex) shown in FIG. 5 corresponds to the grid in FIG. 4 corrected with the constants and coefficients chosen so as to correspond exactly to the characteristics of a real alternator (here a TG15 alternator from VALEO).

The values adopted are stored in memory, once and for all. The memory may be the internal ROM of the microcontroller of the regulator.

For programming the microcontroller enabling the value of IALT to be given in operation, two solutions are proposed, which will now be presented.

According to a first solution, the first step is to calculate the resistance R1 of the armature by means of equation (6). The value of R1 acts to the second order on the output IALT of the alternator. Moreover, the temperature of the armature windings is not accessible if a temperature sensor is not available at these windings (severe environment). It may then be enough to use the temperature θ at the regulator (severe environment, the regulator being in general disposed at the rear of the alternator cage).

It is possible to calculate R1 by directly using equation (6), or choosing a value of R1 as a function of θ among a few values pre-programmed in ROM memory (in this case at least four values of R1 are preferably provided, respectively for four distinct ranges of values of θ).

Then IALT is calculated by means of equations (1) and (7). These equations (1) and (7) each contain the value of IALT. Consequently, the calculation of IALT must be made by successive approximations, commencing for example with IALT=0 in equation (1).

According to a second solution, it is proposed not to directly involve the voltage drop R1×IALT in the value of E1 (that is to say R1=0 is chosen).

Consequently equation (1) becomes:

E1=VALT+VD (10)

and equation (7) is written

$$IALT = ( lex + C 3 ) \times K 1 - \frac{( VALT + VD )}{( ROT + C 4 ) \times K 2} + C 5 \qquad ( 11 )$$

Advantageously, there is then only a single equation for calculating the value of IALT, which facilitates the processing by the microcontroller (there is no longer any calculation by successive approximations). On the other hand, the influence of the temperature must be taken into account by the five constants and coefficients.

For this purpose, at least four sets of constants and coefficients are preferably defined, each set being linked to a given temperature range of the regulator (or better the temperature of the armature winding, if it can be measured).

For example, it is possible to choose the four temperature ranges given in table 1 below, corresponding to thresholds of 50° C. and 100° C.

TABLE 1
Temperature ranges
θ < 0° C.
0° C. < θ < 50° C.
50° C. < θ < 100° C.
100° C. < θ

Consequently, and for this example, the constants and coefficients occupy a memory size (in ROM) of 20 bytes. In the table thus stored in memory, there are read the two multiplying coefficients and the three additive constants corresponding to the temperature range in which the armature winding (or, by default, the battery voltage regulator) is situated when the IALT is calculated.

FIG. 6 gives the equivalent diagram of the alternator according to this second solution (omission of the resistor R1).

With reference to FIG. 7, a description will now be given of an example of an algorithm for reading the constants and coefficients for a given temperature θ of the armature windings or of the regulator according to the second solution. This example corresponds to the case of the four ranges of temperature values defined by table 1 above.

In an initialisation step 71, a variable θ₀ is and a variable N are set to zero.

Next, in a test step 72, the current value θ of the temperature is compared with the variable θ₀.

If θ>θ₀, then, in a step 73, the variable θ₀ is incremented by 50 units and then, in a step 74, the variable N is incremented by 5 units (assuming that a set of constants and coefficients corresponds to 5 memory words to be read in the ROM memory) and the test of step 12 is returned to.

If on the contrary θ<θ₀ then, in a step 75, there are read the values of the coefficients K1 and K2 and the values of the constants C3, C4 and C5 in the ROM memory at the address ADR+N, where ADR designates the address of the first parameter (coefficient or constant) of the first set, in the ROM memory.

FIG. 8 illustrates an example of an algorithm for calculating the output IALT of the alternator according to the second solution, using the constants and coefficients obtained for example by the algorithm in FIG. 7.

In a first step 81, the value of E1 is calculated, by adding the values of VALT and VD, in accordance with equation (10). The values of VALT and of VD are conventionally known to the microcontroller of the regulator. In a step 82, an intermediate value denoted IR2 is next calculated, which corresponds to the sum ROT+C4 of the rotation speed ROT (conventionally known to the regulator microcontroller) and the constant C4 read in memory. Then, in a step 83, the value IR2 is multiplied by the coefficient K2 read in memory. Finally, in a step 84, the value of E1 (calculated at step 81) is divided by the value IR2 (calculated at step 83).

These steps 81-84 make it possible to obtain the second term of equation (11) giving the output IALT of the alternator. It should be noted that the division of step 84 giving the term

$$\frac{E 1}{( ROT + C 4 ) \times K 2}$$

may be difficult to perform
in hardware in the regulator microcomputers, and this is why it can be carried out by program.

In a step 85, the constant C3 read in memory is added to the value of the excitation current lex (which can be measured as indicated in the aforementioned document WO 02/071570), in order to obtain an intermediate value of the output IALT of the alternator. Then in a step 86 this intermediate value of IALT is multiplied by the coefficient K1 read in memory.

These steps 85-86 make it possible to obtain the first term of equation (11) giving the output IALT of the alternator.

In a step 87, the second term (obtained at the end of step 84) is subtracted from the first term (obtained at the end of step 86) in order to obtain a new intermediate value of the output IALT. It should be noted that, for the low values of the rotation speed (lower than the initiation speed), the value obtained may be negative. In this case, a test makes it possible to convert this negative value into a zero value.

To end, in a step 88, the constant C5 read in the ROM memory is added to the intermediate value of the output IALT obtained at step 87, in order to obtain the estimated value IALT of the current output by the alternator.

It should be noted that the order of steps 81-84 on the one hand and steps 85-86 on the other hand may be reversed. Likewise, step 88 can be performed before step 87. In this case, the constant C5 can be added to the second term (obtained at the end of step 84) or to the first term (obtained at the end of step 86).

It should also be noted that the mathematical expression of IALT given by equation (7) can be formulated differently, but the various forms result in the same value of IALT by using appropriate coefficients and constants.

For example, the coefficient K2 can be replaced by 1/K2. In this case, equation (7) becomes:

$$IALT = ( lex + C 3 ) \times K 1 - \frac{E 1 \times K 2}{( ROT + C 4 )} + C 5 \qquad ( 12 )$$

The coefficient K2 can also be replaced by K2/K1. In this case equation (7) becomes:

$$IALT = ( lex + C 3 - \frac{E 1}{( ROT + C 4 ) \times K 2} ) + K 1 + C 5 \qquad ( 13 )$$

There are many combinations possible. The most convenient form for the use of the coefficients and constants will be chosen, that is to say the one that most facilitates the calculations made by the microcontroller of the battery voltage regulator.

In embodiments, the regulation unit of an alternator, i.e. the regulator, comprises not only means for estimating the current output by the alternator as described above, but also means of calculating the mechanical torque Ta applied to the alternator shaft, the useful power Pu and/or the efficiency ρ of the alternator.

This is because the simplified equivalent diagram makes it possible to calculate the current output by the alternator but it is also possible to derive from this, by additional calculations, other characteristics of the alternator such as the mechanical torque, the power and the efficiency of the alternator. The calculations of the torque Ta and efficiency ρ involve the useful torque Tu, the torque Te relating to electrical losses and the torque Tm relating to mechanical losses, which can be obtained by additional calculations from information available at the regulator.

These additional calculations require a greater calculation power than for the calculation of the output current IALT alone. In particular, multiplication and division are often used and are advantageously hard-wired into the microprocessor or microcomputer.

The useful torque Tu depends on the rotation speed ROT and the useful power Pu, which is the electrical power available at the output of the alternator and which is given by the equation:

Pu=VALT×IALT (14)

Starting from the value of the useful power Pu thus calculated, the useful torque Tu is obtained by the following calculation:

$$Tu = \frac{Pu}{ROT} = \frac{VALT \times IALT}{ROT} \qquad ( 15 )$$

The electrical losses depend principally on the resistance R1 of the armature. Consequently the value of the output current IALT that is used is preferably obtained from the simplified equivalent diagram in FIG. 1 since this involves this resistance R1. In this case, the calculation of the output current IALT is made by successive approximations (by 4 iterations for example) as already stated. The torque Te relating to the electrical losses depends on the power lost as electrical losses Pe and on the rotation speed ROT. As a first approximation, the electrical losses Pe are linked to the Joule losses in the resistor R1 and to the voltage drop in the bridge rectifier, which can be estimated at approximately 1.5 volts. As a result the torque Te can be calculated according to the formula:

$$Te = \frac{Pe}{ROT} = \frac{R 1 \times {IALT}^{2} + 1.5 \times IALT}{ROT} \qquad ( 16 )$$

If more precision is required in the calculation of the electrical losses, the value of the resistance R1 can be corrected according to the current IALT output by the alternator, in order to take account of the heating of the armature winding. It is also possible to take account of the resistive losses in the field winding and the magnetic losses, or even of the excitation current lex taken off by the field winding of the alternator.

The mechanical losses are represented by a torque Tm that is variable according to the rotation speed ROT. As a first approximation, this torque Tm is a second-degree function of this rotation speed, because of the losses by ventilation. In other words, the torque Tm can be calculated by the following formula:

Tm=P1×(ROT)²+P1×(ROT)+P3 (17)

where P1, P2 and P3 are coefficients that depend on the characteristics of the alternator concerned (in particular the losses by ventilation, the internal friction being negligible), which are advantageously known from the regulator manufacturer.

The graph in FIG. 9 gives the trend of the torque Tm relating to the mechanical losses calculated according to the above method.

In summary, the calculation of the torques Te and Tm relating to the electrical and mechanical losses respectively requires the following coefficients to be taken into account:

the resistance R1 of the windings of the stator relating to electrical losses; and

coefficients P1, P2 and P3 of the second-degree function, which relate to mechanical losses (essentially the losses by ventilation) of the alternator.

Having calculated the torques Tu, Te and Tm as indicated above it is then possible to calculate the resulting torque Ta applied to the alternator shaft. This is the sum of the useful torque Tu and the torques Te and Tm relating to the electrical and mechanical losses, respectively:

Ta=Tu+Te+Tm (18)

The graph in FIG. 10 gives the trend of the torque Ta thus calculated for various values of the excitation current.

The efficiency ρ of the alternator is the ratio of the useful power Pu to the power applied to the shaft (which corresponds to the product of the corresponding torque Ta and the rotation speed ROT), or the ratio of the useful torque Tu to the torque Ta applied to the shaft. The efficiency ρ of the alternator is therefore calculated by one of the following formulae:

$$ρ = \frac{Pu}{Ta \times ROT} = \frac{Tu}{Ta} \qquad ( 19 )$$

The graph in FIG. 11 gives the trend of the efficiency ρ thus calculated for various values of the excitation current.

Other information again can be calculated from the value of the current IALT output by the alternator, according to requirements, the above information being given only by way of example.

The alternator regulator that comprises the means of implementing the embodiments described above can be produced around a low-cost 8-bit microcontroller, such as a Motorola 6805™.

1. A method of estimating current delivered by an alternator for a motor vehicle comprising a calculation of an output value representing a current delivered by the alternator from a first input value representing an excitation current of the alternator on the one hand, and a second input value representing a rotation speed of the alternator on the other hand, in which the calculation of the output value comprises the steps of:
(a) calculating a first term substantially proportional to the first input value;
(b) calculating a second term substantially inversely proportional to the second input value; and
(c) subtracting said second term from said first term in order to obtain the output value.

2. The method according to claim 1, in which at step (b) the second input value is increased by a first given non-zero additive value.

3. The method according to claim 1, in which at step (a) the first input value is increased by a second non-zero additive value.

4. The method according to claim 1, in which the calculation of the output value also comprises, after step (c), the addition of a third non-zero additive value.

5. The method according to claim 1, in which the second term depends on a parameter representing a temperature of armature windings of the alternator.

6. The method according to claim 1, in which a set of parameters comprising a first multiplying coefficient acting at step (a), a second multiplying coefficient acting at step (b), the first additive value, the second additive value, and/or the third additive value, is selected according to a parameter representing the temperature of armature windings of the alternator.

7. The method according to claim 5, in which the parameter representing the temperature of the armature windings of the alternator is measured at a unit regulating the voltage delivered by the alternator.

8. The method according to claim 1, in which the first input value is measured at a unit regulating a voltage delivered by the alternator.

9. A device for estimating current delivered by an alternator for a motor vehicle comprising means of calculating an output value representing a current delivered by the alternator that are configured so as to calculate said output value from a first input value representing an excitation current of the alternator on the one hand, and a second input value representing a rotation speed of the alternator on the other hand, in which the means of calculating the output value comprise:
(a) first calculation means configured to calculate a first term substantially proportional to the first input value;
(b) second calculation means configured to calculate a second term substantially inversely proportional to the second input value; and
(c) third calculation means configured to subtract the second term from the first term in order to obtain its output value.

10. The device according to claim 9, in which the second calculation means are configured so as to increase the second input value by a first given non-zero additive value.

11. The device according to claim 9, in which the first calculation means are configured so as to increase the first input value by a second non-zero additive value.

12. The device according to claim 9, in which the means of calculating the output value also comprise, after the third calculation means, means for adding a third non-zero additive value.

13. The device according to claim 9, in which the second term depends on a parameter representing a temperature of armature windings of the alternator.

14. The device according to claim 9, also comprising selection means configured to select a set of parameters comprising a first multiplying coefficient acting at step (a), a second multiplying coefficient acting at step (b), the first additive value, the second additive value and/or the third additive value, according to a parameter representing a temperature of armature windings of the alternator.

15. The device according to claim 13, also comprising measuring means for measuring the parameter representing the temperature of the armature windings of the alternator at a unit regulating the voltage delivered by the alternator.

16. The device according to claim 9, also comprising means for measuring the first input value at a unit regulating the voltage delivered by the alternator.

17. A regulation unit regulating the voltage delivered by an alternator for a motor vehicle, comprising a device according to claim 9.

18. The regulation unit according to claim 17, also comprising means of calculating a torque applied to an alternator shaft.

19. The regulation unit according to claim 18, in which the torque applied to the alternator shaft is calculated as a sum of useful torque, the torque relating to electrical losses and the torque relating to mechanical losses.

20. The regulation unit according to claim 19, in which the useful torque is calculated as the ratio of the useful power to the rotation speed of the alternator, the useful power being calculated as the product of the output voltage of the alternator and the estimated value of the current delivered by the alternator.

21. The regulation unit according to claim 19, in which the torque relating to electrical losses is calculated as the ratio of the electrical losses to a rotation speed of the alternator, the electrical losses being calculated by virtue of a second-degree function of the estimated value of the current delivered by the alternator.

22. The regulation unit according to claim 19, in which the torque relating to the mechanical losses is calculated by virtue of a second-degree function of a rotation speed of the alternator.

23. The regulation unit according to claim 17, also comprising means of calculating the efficiency of the alternator.

24. The regulation unit according to claim 23, in which the efficiency is calculated as a ratio of useful torque to the torque applied to an alternator shaft.

25. An alternator for a motor vehicle, comprising a unit regulating the voltage delivered by the alternator according to claim 17.
